(19) United States
(12) Patent Application Publication
(10) Pub. No.: US 2026/0098894 A1
(43) Pub. Date: Apr. 9, 2026

(54) TESTING METHOD AND TESTING INSTRUMENT FOR TESTING ELECTRONIC EQUIPMENT

(71) Applicant: Rohde & Schwarz GmbH & Co. KG, München (DE)

(72) Inventors: Thomas Lutz, München (DE); Max Winklhofer, München (DE); Jens Volkmann, Birnbach (DE); Sebastian Hoehler, Utting am Ammersee (DE); Anton Strohmeier, München (DE)

(21) Appl. No.: 18/906,651

(22) Filed: Oct. 4, 2024

(51) Int. Cl. G01R 31/28

(52) U.S. Cl. CPC G01R 31/2822

(57) ABSTRACT

An RF testing method for testing a plurality of devices under test (DUT) employs a virtual testing instrument having a plurality of testing interfaces. The testing method comprises the steps of: determining, by the testing instrument, an expected interference behaviour between the first and second DUT based on the notified first and second configuration; prioritizing, by the testing instrument, a testing procedure for the first DUT and for the second DUT according to predefined priority criteria; and generating RF test signals for testing the first and second DUT on the basis of as well the prioritizing of the testing procedure and the determined interference behaviour.

Summarizing, both the virtualisation of testing instruments by employing a MUTEX mechanism and at the same time an interference avoiding mechanism is realised at the same time. The present invention further relates to an RF testing instrument for testing a plurality of devices under test.

### FIELD OF THE INVENTION

The present invention relates to a testing method for testing a plurality of devices under test by employing a virtual testing instrument having a plurality of test channels. The present invention further relates to a testing instrument for testing a plurality of devices under test.

### BACKGROUND OF THE INVENTION

Electronic equipment, such as mobile communication devices or mobile computing devices, need to be tested after production in order to ensure proper configuration, calibration and functionality. For testing purposes, specific testing devices are employed which simulate a testing environment under predefined testing conditions, e.g. specific testing routines with predefined testing schedules. Those testing schedules regularly involve input of particular test signal sequences into a device under test (DUT) and/or reception of responses to testing signals input to the DUT. Such responses may be evaluated for consistency, constancy, timeliness and other properties of an expected behaviour of the DUT.

Of particular relevance are tests and test instruments for electronic equipment which are operated in an environment sensitive to radio frequency (RF) signals. Such test instruments may be used to output, receive, measure or otherwise process RF-sensitive parameters and signals. Those tests are conventionally performed using standardized testing routines conducted by specifically designed testing equipment that is connected to a DUT.

Testing contemporary DUTs is time-consuming and as such cost intensive: Given the high complexity of modern electronic equipment and its proliferation as mass product, testing each and every DUT suffers from potentially low throughput and high costs associated with the testing cycles, slowing down manufacturing processes and verification procedures. Thus, there is an increasing demand in solutions for testing multiple electronic devices in an efficient manner.

High cost associated with the testing of DUTs can be reduced by virtualizing test instruments, e.g. by reducing the number of required test instruments and by increasing the throughput. This approach is disclosed in US 2016/0259700 A1. The focus described in this approach is on simple handling, which ideally involves no further effort, although the available measurement resource of a single test station has been converted into a multiple test station.

One issue arising from this scenario refers to impairments that may result from the interference of signals which cannot be adequately shielded from each other, for example when a DUT testing a transmitter on a specific frequency or channel emits a signal with a high signal level, while at the same time for the testing of a receiver with a low signal level is being carried out on the same frequency channel on another DUT.

### SUMMARY OF THE INVENTION

Against this background, there is a need to avoid interferences in a RF test stations without significantly increase the complexity of the control software.

According to the disclosure of present invention, a testing method and a testing instrument are provided.

According to a first aspect, a testing method for testing a plurality of RF devices under test (DUT) by employing a virtual testing instrument having a plurality of RF test channels is provided. The testing method comprises the steps of: providing, on a first RF test channel of the testing instrument, a first DUT having a first configuration; providing, on a second RF test channel of the testing instrument, a second DUT having a second configuration; notifying to the testing instrument the first configuration and second configuration by the first DUT and second DUT, respectively; determining, by the testing instrument, an expected interference behaviour between the first DUT and second DUT based on the notified first and second configurations; prioritizing, by the testing instrument, a testing procedure for the first DUT and for the second DUT according to predefined priority criteria; and generating RF test signals for testing the first and second DUT on the basis of as well the prioritizing of the testing procedure and the determined interference behaviour.

According to a second aspect, a testing instrument for testing a plurality of RF devices under test (DUT) is provided. The testing instrument comprises: at least two test interfaces for coupling at least two DUTs having different configurations to the testing instrument; a vector signal generator -VSG-coupled to the test interfaces and configured to generate RF test signals for the testing of at least one of the coupled DUTs; a vector signal analyser—VSA—coupled to the test interfaces and configured to analyse RF test response signals received from at least one of the coupled DUTs; a buffering module coupled to the test interfaces and configured: to receive configuration information from the DUTs coupled to the test interfaces; to prioritize a testing procedure for first DUT and for a second DUT according to predefined priority criteria; to determine an expected interference behaviour between the first DUT and the second DUT based on their notified configurations; and to generate RF test signals for testing the first DUT and second DUT on the basis of as well the prioritizing of the testing procedure and the determined interference behaviour.

The present disclosure provides a solution for so-called virtual testing instruments that provide at least two and in particular a plurality of test channels for the testing of at least two and preferably a plurality of DUTs. For this kind of testing, a specific prioritizing mechanism is implemented which determines the sequence of the tested DUTs in the virtual testing instrument.

One further idea of the present disclosure is to implement a specific synchronisation mechanism when testing DUTs at different channels at the same time. It is a finding of the present disclosure that in case that different DUTs are tested at different channels of the virtual testing instrument, there is the risk of interferences. According to the present disclosure, a specific mutual exclusion (MUTEX) mechanism is implemented for avoiding these interferences by employing external process control. This way, the measurement is delayed until the interference conflict has been resolved, i.e. a signal generator or the DUT are no longer transmitting RF signals and the measurement has been completed.

Summarizing, both the virtualisation of the testing instrument by employing a MUTEX mechanism and at the same time an interference avoiding mechanism is realised at the same time.

Advantageous configurations and developments emerge from the further dependent claims and from the description with reference to the figures of the drawings.

According to a specific embodiment, the step of generating test signals comprises a synchronizing step such, that a testing procedure for testing the second DUT is started only after the testing procedure for testing the first DUT is finished.

According to a further embodiment, in the step of generating the test signals, when testing a first DUT the testing of the second DUT is delayed until a determined interference between the first and second test channel is below a predefined value. In particular, according to a specific embodiment, the predefined interference is zero.

According to a specific embodiment, the step of determining an expected interference behaviour comprises optimizing the test procedure for the first and second DUT such that the interference between the first and second DUT is reduced.

According to a specific embodiment, for determining the expected interference behaviour at least one of the following information are taken into consideration: the frequency ranges of the test signals for testing the first and second DUTs are at least partially overlapping; an expected reception level of a test receiver within the test instrument conflicts with the test signal level of a signal generator within the test instrument and the expected signal-noise-ratio; test signals from two or more signal generators within the test instrument are overlapping in two or more measurement channels.

According to a specific embodiment, the first configuration and the second configuration of the first DUT and the second DUT, respectively, comprise at least one of the following testing parameters: a bandwidth used in the respective test channel for testing the respective DUT; a frequency used in the respective test channel for testing the respective DUT; a signal power of a test signal used in the respective test channel for testing the respective DUT.

According to a specific embodiment, the configuration of a DUT is changed from a first testing cycle to a subsequent second testing cycle that is carried out on the same DUT and wherein the corresponding DUT notifies this change of its configuration to the testing instrument.

According to a specific embodiment, the at least one of the first and second configurations is modified after performing a predefined number of test cycles and wherein the testing of the first and second DUT, respectively, is then repeated or continued on the basis of the modified configuration.

According to a specific embodiment, at least one of the first and second configurations is modified after performing a predefined number of test cycles and wherein the testing of the first and second DUT, respectively, is repeated on the basis of the modified configuration.

According to a specific embodiment, the step of generating the test signals comprises a lock command that contains locking information that is used to lock the testing instruments regardless that the DUT is already transmitting test signals.

According to a specific embodiment, the predefined priority criteria comprise FCFS (“first-come, first-served”) criteria. According to a specific embodiment of the testing instrument, the test interface comprises at least four input/output ports and preferably at least eight I/O ports configured to be—I/O—connected to the DUTs.

According to a specific embodiment of the testing instrument, the testing instrument further comprises a switch configured to selectively switch the I/O ports of the test interface to one of the VSA and VSG.

According to a specific embodiment of the testing instrument, the at least two test interfaces comprise at least one of: a USB port; a PCIe port; a Thunderbolt port; a Firewire port.

According to a specific embodiment of the testing instrument, the buffering module comprises at least two controller-specific databases and wherein the buffering module is further configured to store received RF test response signals from the plurality of DUTs in at least one of the plurality of controller-specific databases.

Where appropriate, the above-mentioned configurations and developments can be combined implementations can be combined with each other as desired, as far as this is reasonable. Further possible configurations, developments and implementations of the invention also include combinations, which are not explicitly mentioned, of features of the invention which have been described previously or are described in the following with reference to the embodiments. In particular, in this case, a person skilled in the art will also add individual aspects as improvements or supplements to the basic form of the present invention.

### BRIEF DESCRIPTION OF THE DRAWINGS

Further details, aspects and embodiments of the invention will be described, by way of example only, with reference to the accompanying drawings. Elements in the drawings are illustrated for simplicity and clarity and have not necessarily been drawn to scale.

FIG. 1 schematically illustrates a testing instrument for testing a plurality of RF devices under test.

FIG. 2 shows a flow diagram illustrating a testing method for testing a plurality of RF devices under test.

FIG. 3a-3c show signal-time-diagrams for illustrating embodiments for the sequences of a single test sequence.

FIG. 4 shows an example of the method according to the present invention which employs an interference protection.

FIG. 5 schematically illustrates a modular testing system according to a further embodiment of the invention.

FIG. 6 schematically illustrates a modular testing system according to another embodiment of the invention.

FIG. 7 schematically illustrates a testing front end module according to a further embodiment of the invention.

FIG. 8 shows a signalling sequence chart of signals for a testing method for testing electronic equipment according to another embodiment of the invention.

FIG. 9 shows a flowchart of procedural stages of a testing method for testing electronic equipment according to a further embodiment of the invention.

The appended drawings are intended to provide further understanding of the embodiments of the invention. They illustrate embodiments and, in conjunction with the description, help to explain principles and concepts of the invention. Other embodiments and many of the advantages mentioned become apparent in view of the drawings. The elements in the drawings are not necessarily shown to scale. In the drawings, like, functionally equivalent and identically operating elements, features and components are provided with like reference signs in each case, unless stated otherwise.

### DETAILED DESCRIPTION OF THE EMBODIMENTS

FIG. 1 illustrates a RF testing instrument for testing a plurality of RF devices under test (DUT).

In FIG. 1, the testing instrument is denoted by reference numeral 100. The testing instrument comprises in the embodiment of FIG. 1 several test interfaces 110, a vector signal generator (VSG) 120, a vector signal analyser (VSA) 130 and a buffering module 140.

In the embodiment of FIG. 1, two test interfaces 110 are shown for coupling two DUTs 150. However, it should be noted that the testing instrument 100 may also comprise a higher number of test interfaces 110 in order to be prepared for the testing of a corresponding number of DUTs 150.

According to this disclosure, the testing instrument 100 acts as a virtual testing instrument 100 that is configured to test different DUTs 150 at the same time without employing different testing instruments for this purpose. The different DUTs 150 may be tested by the testing instrument 100 regardless whether they comprise identical test configurations or different test configurations.

US 2016/0259700 A1 describes an example of such a virtual test instrument that comprises a plurality of RF test channels for the testing of a plurality of DUTs. US 2017/0126336 A1 describes the prevention of interferences through MUTEX handling by employing external process control and in particular the prioritized handling of different DUTs that are coupled to different ports of the test interface. US 2016/0259700 A1 and its content is herewith fully incorporated by reference.

The vector signal generator (VSG) 120 is coupled to the test interface 110 and configured to generate RF test signals for the testing of a DUT 150 coupled to the corresponding test interface 110.

The vector signal analyser (VSA) 130 is coupled to the test interface 110 and configured to analyse RF test response signals received from a tested DUT 150 coupled to the corresponding test interface 110.

The buffering module 140 is coupled to the test interface 110 and preferably to the VSG 120 and VSA 130. The buffering module 140 is configured to receive configuration information from the DUTs 150 and to determine an expected interference behaviour between the both DUTs 150 coupled to the test interface 110 based on their configurations. The buffering module 140 employs a MUTEX procedure for the testing of the different DUTs 150 by prioritizing a testing procedure for the DUTs 150 according to predefined priority criteria. Finally, the buffering module 140 generates RF test signals for testing the DUTs 150 on the basis of as well the prioritizing of the testing procedure and the determined interference behaviour.

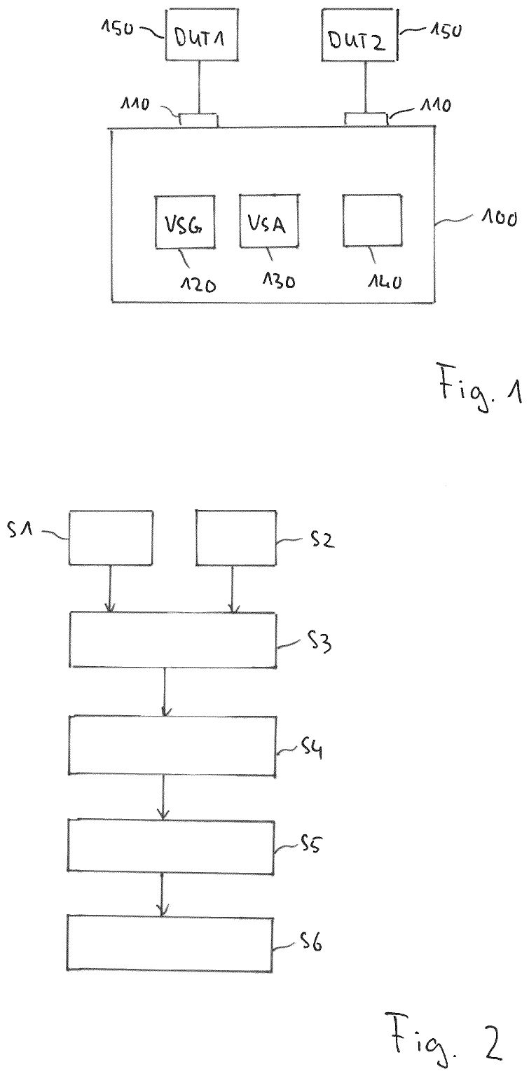

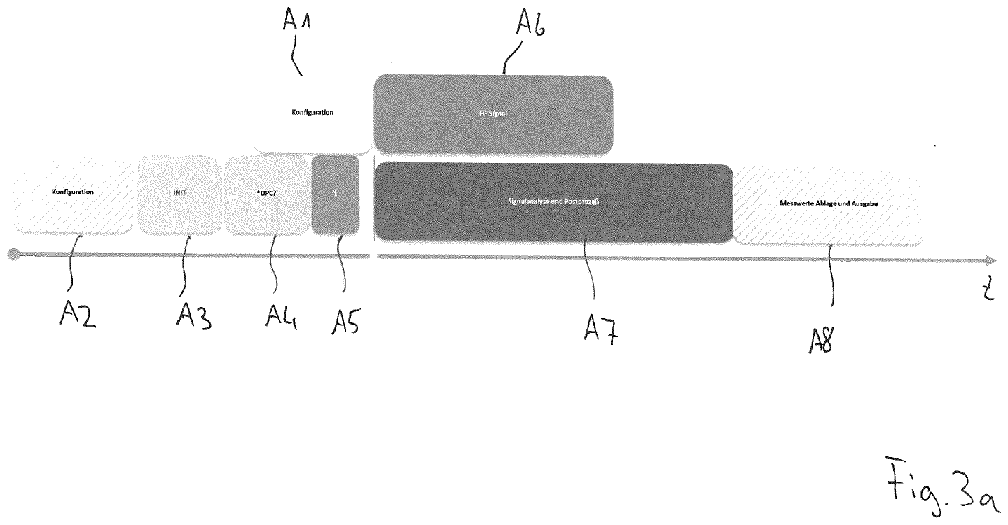

FIG. 2 shows a flow diagram illustrating a testing method for testing a plurality of RF devices under test by employing a virtual testing instrument having a plurality of RF test channels shown in FIG. 1. The testing method comprising the following steps:

In a first step S1, a first DUT 150 having a first configuration is provided. For example, the first DUT 150 is coupled to a test interface 110 of the testing instrument 100 that forms part of a first RF test channel.

In a further step S2, a second DUT 150 having a second configuration is provided. For example, the second DUT 150 is coupled to a test interface 110 of the testing instrument 100 that forms part of a second RF test channel.

Both, the first and second DUTs 150 notify in a subsequent step S3 their configurations to the testing instrument 100, i.e. the first DUT 150 notifies its first configuration and the second DUT 150 notifies its second configuration. The notifying of the configuration to the testing instrument 100 may be done by using a specific notification command which is generated and submitted in each case by the corresponding DUT 150.

In step S4, the testing instrument 100 determines an expected interference behaviour between the first and second DUT 150 based on the notified first and second configurations.

In steps S5, the testing instrument 100 prioritizes a testing procedure for the first DUT 150 and for the second DUT 150 according to predefined priority criteria.

Finally, in step S6 RF test signals for testing the first and second DUT are generated. According to the present invention, the generation of the RF test signals is made on the basis of as well the prioritizing of the testing procedure and the determined interference behaviour.

It should be noted that the sequence of the steps may be varied, in particular with regard to the steps S3-S5.

Hereinafter, the present invention is described in more detail. Before doing so, the test environment is briefly described:

### Signal Analysis

The (vector) signal analyser 130 for analysing an RF test or measurement signal is able to determine the necessary resources based on the setting of the test or measurement. The resources may be:
The frequency range/spectrum of the RF test signal;
The expected level of the RF test signal;
specific signal requirements, which are derived from test conditions, e.g. wider or narrower frequency spectrum depending on the test mode;
minimum test requirement in terms of dynamics.

### Signal Generation

The (vector) signal generator 120 that is employed for the generation of the test signal has information about the signal shape of test signal. For example, with arbitrary waveform generators (shortly ARB generators), the spectrum of a RF test signal can be derived from the sample rate. However, it is even more advantageous when using an RF test signal description that is part of the ARB file or when a signal analysis (e.g. via FFT) determines the bandwidth of the signal when loading the ARB file in the testing instrument. In particular, the used signal generator 120 has the following information:
The frequency range/spectrum of the RF test signal;
The expected level of the RF test signal;
The expected signal-to-noise ratio (SNR), which enables a receiver the testing without significant measurement errors.

### Signal/transmission Path

It is important to consider the transmission channel with regard to the individual RF test signals. The higher the isolation of the RF test signals (end to end), the lower the restrictions resulting from test signal interferences. The transmission test channel is determined amongst others by:
Path attenuation for the different test channels, determined over used frequency ranges for the testing of the different DUTs.
Isolation of different DUTs from each other. It is expected that a “worst case” recording should be sufficient, since the highest interference will typically occur for adjacently arranged DUTs. The isolation of immediate DUT neighbours should be recorded the isolation values are preferably stored in the testing instrument.

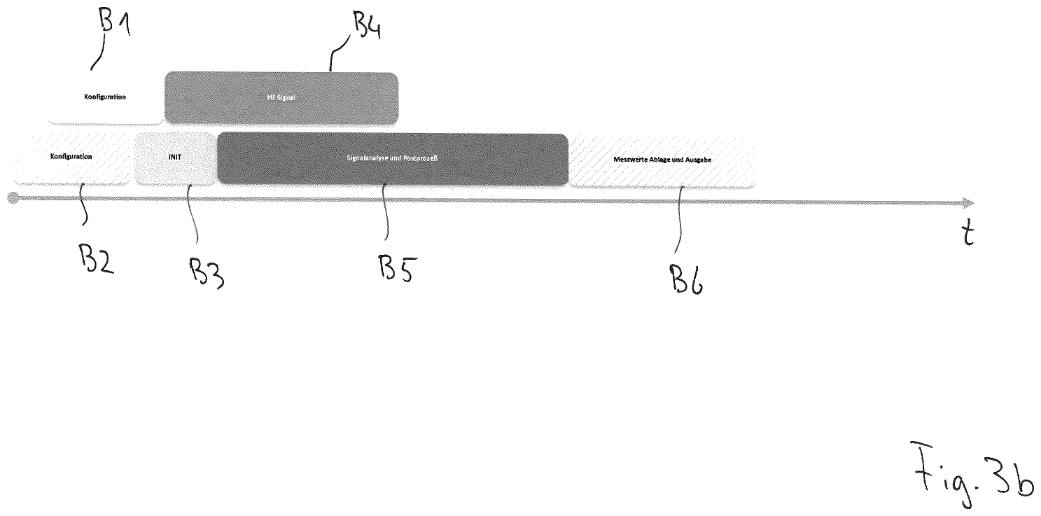

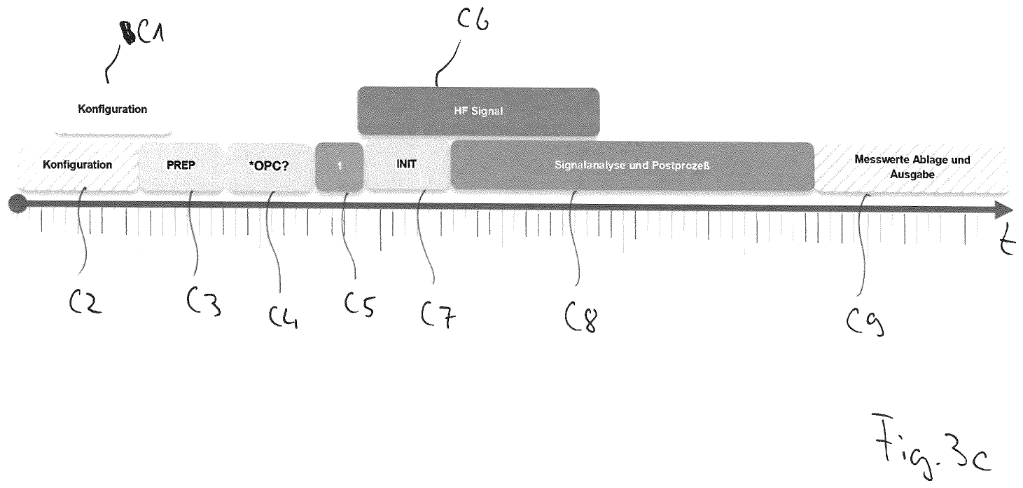

While the generator settings and the testing instrument settings can be processed directly by the test instrument firmware, the parameters of the signal path are individual. These parameters of the signal path vary depending on the test setup and require input by the customer's test software and corresponding consideration in the test instrument firmware. Before describing the test procedure according to the invention, hereinafter the test procedure of a conventional test is described by mans of the illustrations of FIG. 3a-3c.

FIGS. 3a and 3b show signal-time-diagrams for illustrating the sequence of a single testing sequence. As described before, a test instrument comprises a signal generator and a signal analyser (not shown in FIGS. 3a, 3b). In FIGS. 3a, 3b, the above signal components refer to the DUT and the below signal components refer to the signal analyser. A test procedure in the remote control consists of the following test stages, depending on the type of test signal:

### Trigger Event

A test procedure is based on a specific trigger event or signal, that is for example derived from the RF test signal to be transmitted, e.g. a power trigger. This example, that is shown in FIG. 3a, comprises the following test stages:
Configuration A1, A2 of a measurement. This may be done by storing the configuration parameters in a database.
Requesting A3 the measurement (INIT).
Signalizing A4, A5 that the test is ready for start. Returning of an ‘Operation Complete’ (*OPC) message to the control programme.
The DUT transmits its RF signal A6 which triggers the test and its analysis A7.
The test signal recording is completed and the test and analysis results are determined. The test and analysis results may be stored in a suitable database A8.

The INIT signal is a kind of measurement initializing which starts a DUT and/or measurement. The *OPC signal is used to avoid infinite loops.

### Continuous Transmitted Signal

A test procedure may also be based on a continuously transmitted signal, which changes the time sequence. This example, which is shown in FIG. 3b, comprises the following test stages:
Configuration B1, B2 of a measurement. This may be done by storing the configuration parameters in a database.
The DUT transmits B4 its RF signal.
Requesting B3 the measurement (INIT).
The test signal recording is executed completed post-processed B5. Then the test and analysis results are determined.
The test and analysis results may be stored in a suitable database B6.

### Continuous Transmitted Signal With Prep Command

A test procedure may also be based on a continuously transmitted signal together with a PREP command that is intended to provide an additional synchronisation. The PREP command basically locks the corresponding hardware until the actual test and measurement has started. In this explicit case, the DUT already transmits an RF test signal before the analyser has received the INIT signal and before the test measurement has started.

This example, which is shown in FIG. 3c, comprises the following test stages:
Configuration C1, C2 of a measurement. This may be done by storing the configuration parameters in a database.
A PREP command is provided to lock the signal analyser C3.
The DUT transmits B3 its RF signal.
Requesting B4 the measurement (INIT).
Signalizing C4, C5 that the test is ready for starting. Returning of an “Operation Complete” (*OPC) message to the control program. However, this step is principally redundant since the analysing step is preferably started immediately after releasing the INIT-step C7.
The DUT transmits C6 its RF signal.
The test signal recording is executed completed post-processed C8. Then the test and analysis results are determined.
The test and analysis results may be stored in a suitable database C9.

The function of the generator is analogous to the DUT and the test analyser.

FIG. 4 shows an example of the method according to the present invention which employs an interference protection.

As described with regard to FIG. 1, the testing instrument 100 comprises a signal generator 120 and a signal analyser 130. In FIG. 4, two virtual test channels T1, T2 are shown as examples. Different from the detailed illustration of the different test stages of a test procedure shown with regard to FIG. 3a-3c, in the illustration of FIG. 4 only the phases that are relevant for test control or generator control are shown and considered, as well as the critical phases in which RF test signals can possibly produce interferences.

In the signal-time-diagrams of FIG. 4, D1, refers to the initialisation of the measurement (INIT), D2 refers to the start of the generator, D3 refers to the *OPC/SCPI query for the measurement and generator, D4 refers to the phase of an active RF test signal and D5 refers to the phase of an active generator signal.

The *OPC/SCPI query comprises a query for signalising “operation complete” with the return of a “1” that signalises that the signal is present at the generator or as a sign that the test has been started and is waiting for an RF test trigger. Without interference protection, there is the chance of an overlap between the generator signal D5 and the tests sequences D4 resulting to an interference situation. For example, the generator may produce generator signals with a level of −70 dBm and the DUT transmits a RF test signal with a level of +20 dBm on the same channel. The isolation between the DUTs is in the range of 60 dB. In this case, in case of an intereference situation, the DUT on test channel T1 sees the TX signal of the DUT on test channel T2 at −40 dBm during its RX sensitivity measurement and thus stronger than the test signal. Consequently, the receiver measurement will be incorrect.

However, according to the present invention, the buffering module 140 within testing instrument 100 is configured such to delay the test and measurement in the test channel T2 until a resource conflict has been resolved, i.e. the generator is no longer transmitting a signal in test channel T1 and the receiver measurement has preferably been completed.

The simplest way to avoid conflicting interference relevant situations is to control the generator and the analyser in such a way that simultaneous use of the generator and the analyser is excluded. However, in some test environments and situations this will probably occur too often and in addition limit the possible measurement capacity too much, the idea of the present invention is to somehow block the generator and analyser only in those situations where there is if an overlap of signals in the different test channels that would result in an unwanted interference. This way, the present invention proposes a delay strategy for avoiding interferences.

US 2017/0126336 A1 describes an example of a testing apparatus that employs interferences avoiding strategy. US 2017/0126336 A1 and its content is herewith fully incorporated by reference.

An overlap of signals can occur for the following situations:
When frequency ranges are intersecting;
When the expected reception level of the test receiver (analogue to the emitted transmission power of the DUT) conflicts with the generator level and the expected signal-to-noise ratio;
When signals from two or more generators overlap in such a way that interference occurs.
When signals from two or more DUTs overlap on two or more physical test channels in such a way that interference occurs.

The following also applies:
Levels are corrected for the characteristics of the transmission channel (attenuation and isolation);
The aim is to use only potential conflicts when controlling the timing behaviour in resource control;
Conflicts result from a spectral overlap and a simultaneous overlap of the dynamic requirement.

In principle, the testing instrument knows the times at which RF test signals will most likely overlap. This results from the duration of how long a generator signal is output or the duration of how long the recording of an RF test signal takes in the measuring receiver. However, the testing instrument is unaware of phases in which a DUT is already transmitting and the measurement has not yet been started, or is still transmitting although the measurement has already been completed. US 2016 025970 A1 describes that it is sufficient to consider the following phases for the synchronisation of the remote control application with the measurement control in the measuring device:
INIT to Operation Complete (*OPC)
Start of the generator until Operation Complete (*OPC)

According to an additional aspect, an additional synchronisation is employed for this purpose. This additional synchronisation employs an additional so-called PREP command, which basically locks the corresponding hardware until the actual test and measurement has started. In this explicit case, the DUT already transmits an RF test signal before the analyser has received the INIT signal and before the test measurement has started.

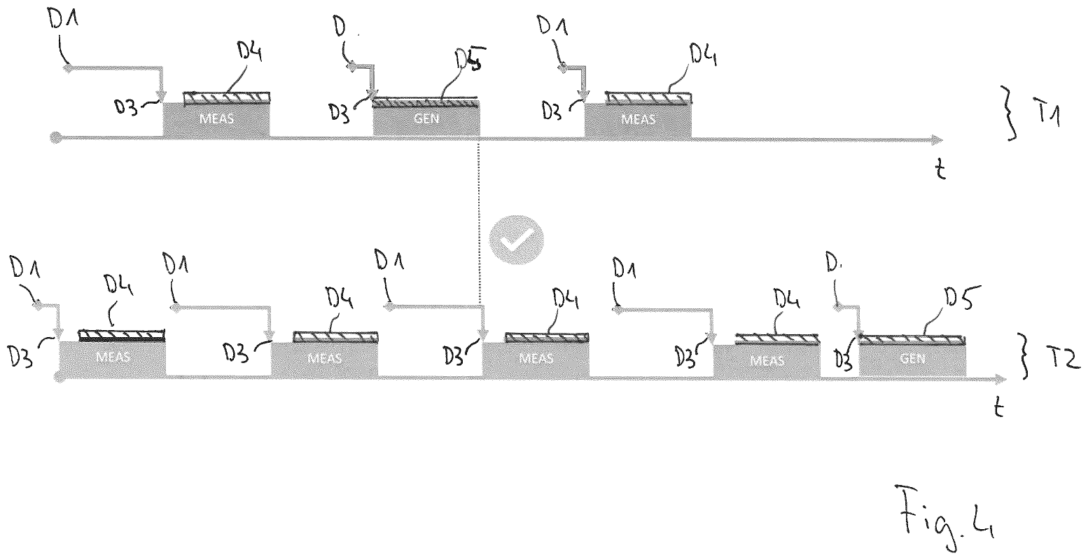

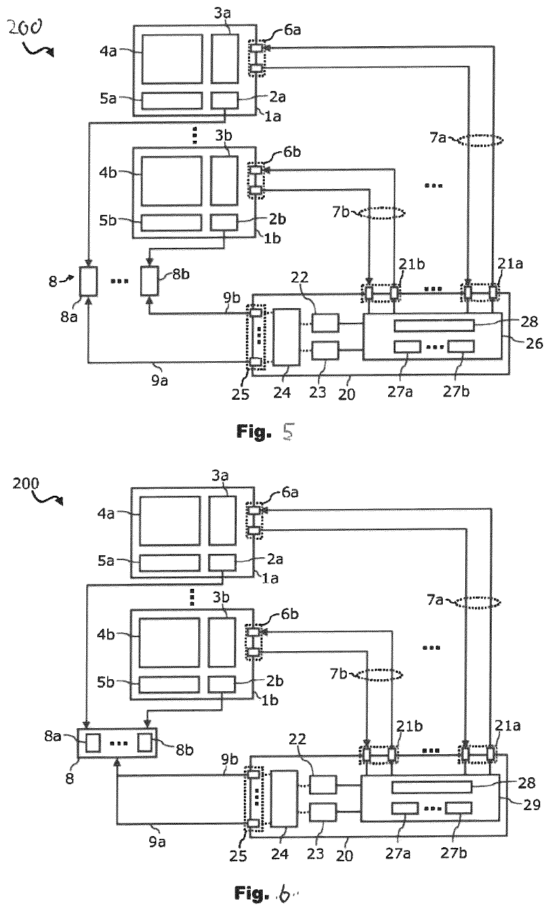

FIGS. 5 and 6 schematically illustrate modular testing systems 200. The modular testing systems 200 may be employed to perform functional tests and testing routines on one or more DUTs which are generally denoted with reference sign 8 in FIGS. 5 and 6. Specifically, the modular testing systems 200 may be used to perform tests for mobile communication or computing devices such as laptops, notebooks, tablets, smartphones, mobile phones, pagers, PDAs, digital still cameras, digital video cameras, portable media players, gaming consoles, virtual reality glasses, mobile PCs and similar electronic equipment. Of course, it should be recognized that other non-mobile electronic equipment may be tested as well, such as—but not limited to—industrial field devices, radio communication base stations, video and TV devices, audio devices like loudspeakers and similar.

The number of DUTs 8 to be tested simultaneously or in parallel is in general not limited to any particular number, but will be determined by the properties and facilities of the testing equipment employed, as will be detailed hereinbelow. Generally, it is desirable to test as many DUTs 8 as possible at the same time in order to increase the efficiency of the testing routines and to keep the overall testing time for a batch of DUTs 8 as short as possible.

Referring to FIGS. 5 and 6, a modular testing system 200 comprises two separate backend controllers 1a and 1b and a testing front end module 20 coupled to the controllers 1a and 1b. The modular testing system 200 may comprise a number of DUTs 8 which are coupled to the at least testing front end module 20 on one hand and to one of the backend controllers 1a and 1b on the other hand.

The testing front end module 20 and the back end controllers 1a, 1b basically correspond to the testing instrument 100 of FIG. 1.

With reference to the backend controllers, the common features are denoted in FIGS. 5 and 6 with the suffix “a” for the first of the backend controllers 1a and with the suffix “b” for the second of the backend controllers 1b. Without loss of generality, the components of both backend controllers 1a and 1b are explained hereinforth in terms of the reference signs without the respective suffix “a” or “b” in each case. Each backend controller 1 may include a testing device controller 2, a testing routine controller 3, a display 4 and one or more input devices 5. In particular, the controllers 1 may comprise a conventional personal computer or a data processing apparatus such as a tablet, a laptop, a notebook, a desktop PC or a similar computing device. The one or more input devices 5 may for example comprise a mouse, a trackball, a keyboard and/or similar user actuated controlling devices. Upon input of commands and/or upon reception and transmission of testing signals the display 4 may be configured to display relevant information to the user of the controller 1. The controller 1 may further comprise one or more central processing units, memory devices, power supply devices and similar apparatuses common for computing devices.

The controller 1 further comprises a controller testing interface 6, for example a USB interface, a PCIe (“Peripheral Component Interconnect Express”) interface, a Thunderbolt interface or a Firewire interface. Depending on the type of interface, the controller testing interface 6 may comprise one or more ports to which electrical connectors such as cables may be connected to form wired connections between the controller 1 and the testing front end module 20. The electrical connectors may for example be USB cables, PCIe cables, Thunderbolt cables or Firewire cables.

The length of the electrical connector(s) 7 used to form the wired connections between the controller 1 and the testing front end module 20 may in particular be larger than about 1.5 metres (60 inches), particularly larger than about 2 metres (80 inches), and more particularly larger than about 2.5 metres (100 inches). This has the advantage that there is some leeway in placing the testing front end module 20 near the DUTs 8 and remotely placing the controller 1 at a more convenient and better accessible workplace. The data rate of data transmitted between the controller 1 and the testing front end module 20 via the wired connections in form of the electrical connector(s) 7 may in particular be larger than 1 Mbps, particularly larger than 2 Mbps, more particularly larger than 10 Mbps. The wired connections may be full duplex or at least half-duplex.

The testing routine controller 3 of the controller 1 may be configured to generate testing routine signals to be sent to the testing front end module 20. The testing routine signals may be generated according to the desired testing routine to be performed on one or more of the DUTs 8 respectively coupled to the particular controller 1. The testing routine signals may involve instructions on specific testing signals or testing signal sequences and their respective properties like signal frequency, signal amplitude, signalling strength, pulse duration, pulse rate or similar. The testing signals to be generated on the basis of the testing routine signals may then be generated in the testing front end module 20 upon receipt at its testing signal interface.

The testing routine controller 3 of the controller 1 may further be configured to evaluate any testing response signals that are received from one or more of the plurality of DUTs 8 respectively coupled to the particular controller 1. The testing response signals may collectively be received by the testing front end module 20 in an expected response to one or more of the testing signals emitted by the testing front end module 20. Alternatively or additionally, the testing response signals may be received by the testing front end module 20 upon direct instructions to the DUTs 8 sent by the testing device controller 2.

The testing device controller 2 may be directly (via wire or wirelessly) coupled to each one of the plurality of DUTs 8 and may send out instructions for the DUTs to emit testing response signals. For example, the testing device controller 2 may elicit the DUTs to transmit specific signals or signal sequences of predefined properties, such as signal frequency, signal amplitude, signalling strength, pulse duration, pulse rate or similar.

The DUTs 8 are in turn connected to input/output ports of a testing device interface 25 of the testing front end module 20. As exemplarily shown in FIG. 5, each of the DUTs 8a, 8b is connected by cable 9a, 9b to one of the input/output ports of the testing device interface 25.

Alternatively or additionally, it may be possible to connect one DUT 8 to more than one of the input/output ports of the testing device interface 25, as exemplarily shown in FIG. 6. For example, in FIG. 6 DUT 8 that have more than one subcomponents 8a, 8b to test, such as for example MIMO antennae, processing chips or similar components, may be subject to concomitant tests over different test channels.

Thus, such DUTs 8 may be connected to different input/output ports at the same time.

The number of input/output ports of the testing device interface 25 is in principle not limited. However, the number of input/output ports may be four or more, more particularly eight or more. The number of input/output ports will determine how many DUTs and/or how many testing routines may be tested in parallel.

In each of the modular testing systems 200, two or more backend controllers 1a, 1b are connected to the testing front end module 20 at the same time. Each of the controller testing interfaces 6a, 6b of the controller 1a, 1b is connected to a different one of a plurality of testing signal interfaces 21a, 21b of the testing front end module 20. In those embodiments, the controllers 1a, 1b may simultaneously gain access to the functionality of the testing front end module 20 to be able to test an even greater number of DUTs 8 at the same time. Furthermore, due to the physical separation of the backend controllers 1a, 1b from the testing front end module 20, the controllers 1a, 1b may be in physically separate locations, yet still simultaneously perform testing routines on DUTs 8 in the same location.

The two or more separate backend controllers 1a, 1b may or may not be in communication with each other. Particularly, when the controllers 1a, 1b are not in communication with each other they may perform testing routines on their respectively coupled DUTs 8a, 8b separately and asynchronously. In that case, the testing front end module 20 may be equipped with means to internally balance access of the different controllers 1a, 1b to the commonly employed functional components of the testing front end module 20. That way, the controllers 1a, 1b may perform pipelined testing routines on the DUTs 8a, 8b connected to the same testing front end module 20, i.e. in virtual synchronization.

FIG. 7 schematically illustrates a testing front end module 20 as it may be employed in any of the modular testing systems 200 of FIGS. 5 and 6. The details of the testing front end module 20 as shown in FIG. 7 are of exemplary nature - it should be understood that different configurations may be possible for the testing front end module 20 depending on the type and nature of the DUTs and test to be performed. Moreover, not every testing front end module 20 within the scope of the disclosure does necessarily need to have each and every subcomponent as exemplarily depicted in FIG. 7.

The testing front end module 20 generally comprises two or more testing signal interfaces 21a, 21b, a vector signal generator (VSG) 22, a vector signal analyser (VSA) 23, a multiplexer/demultiplexer (MUX/DEMUX) 24 and a test device interface 25. The testing signal interface 21 is coupled to each of the VSG 22 and VSA 23 via a respective testing signal interface port 21a and 21b. The testing signal interface 21 may in particular be any of a USB interface, a PCIe interface, a Thunderbolt interface or a Firewire interface.

The VSG 22 is configured to generate testing signals for testing DUTs that may be connected to the test device interface 25 of the testing front end module 20. Upon reception of testing routine signals from one of the backend controllers, such as the controllers 1a and 1b of FIGS. 5 and 6, via one of the testing signal interfaces 21a, 21b, the VSG 22 may generate the testing signals using a processing circuit 10 connected testing signal interface 21. The processing circuit 10 may comprise a processor 18, for example a PLD such as an FPGA or an ASIC. The processing circuit 10 may further comprise a memory 19 such as a flash memory to store firmware, operating software and predefined configuration values used for the operation of the processor 18.

Downstream of the processing circuit 10, the VSG 22 may comprise a digital-to-analog converter 11, an RF up-converter 12 and/or a (pre-)amplifier 13. The digital-to-analog converter 11 may be configured to convert the digital testing signals generated by the processing circuit 10 to analog testing signals which are subsequently mixed to the testing frequency with the RF up-converter 12 using a local oscillator frequency. The up-converted testing signals may then be suitably amplified in order to prevent power loss during the subsequent splitting of the testing signals.

The VSA 23 is also coupled to the testing signal interfaces 21 and is configured to receive testing response signals from a plurality of DUTs connected to the test device interface 25. In order to receive and pre-process the testing response signals, the VSA 23 may comprise a (pre-)amplifier 13, an RF down-converter 12 coupled downstream of the amplifier 13 and an analog-to-digital converter 11. The analog-to-digital converter 11 is coupled to a processing circuit 10 which may comprise—similar to the processing circuit 10 of the VSG 22—a processor 18 and a memory 19. The received testing response signals are amplified by the amplifier 13, down-converted to baseband using the RF down-converter 12 and digitized by the analog-to-digital converter 11. The digitized testing response signals are then pre-processed by the processing circuit 10 and transmitted to a respective one of the backend controllers 1a, 1b via one of the testing signal interfaces 21a, 21b for further evaluation and processing. In that regard, the processing circuit 10 and of the VSA 23 does not need to have full testing evaluation capacity and may be kept lightweight and simple.

Both the VSG 22 and the VSA 23 may comprise a separate power supply port 26a and 26b which may be integrated into a common power supply interface of the testing front end module 20. With the separate power supply ports 26a and 26b, the energy demand of the VSG 22 and VSA 23 may be met without the need for a module-internal power supply. To this end, an external power supply may be coupled to the power supply interface of the testing front end module 20. This enables the testing front end module 20 to be kept lightweight and renders a simple cooling concept possible. The cooling may for example be performed by implementing cooling fins on the outside of the housing or shell of the testing front end module 20.

The VSG 22 and the VSA 23 are both coupled to a multiplexer/demultiplexer (MUX/DEMUX) 24. The MUX/DEMUX 24 is generally configured to multiplex the received testing response signals from the DUTs for reception by the VSA 23 and to demultiplex the generated testing signals by the VSG 22 for distribution among the DUTs. The MUX/DEMUX 24 is coupled to the test device interface 25 that may comprise a number of input/output ports 25a, 25b coupled to respective pins of the MUX/DEMUX 24 downstream of the VSG 22 and VSA 23.

The MUX/DEMUX 24 may comprise a multiplexing fabric 14 which switches the inputs of the VSG 22 and VSA 23 to a set of independently controllable attenuators 15. The attenuators 15 may be advantageously used for selective attenuating the power of the respective testing signal channels to the respective DUT connected to the channel. The attenuators 15 may for example comprise Lange or Wilkinson couplers, for example with a coupling factor of 3 dB. The attenuators 15 may be coupled to a set of independently controllable calibration units 16 which may be used to calibrate the MUX/DEMUX 24 and its transient power dissipation. The calibration units 16 may advantageously allow the selective activation of a feedback loop between the VSG 22 and the VSA 23 to calibrate both devices. The calibration units 16 may be coupled to a switch fabric 17 which is configured to selective switch the input/output ports 25a, 25b of the test device interface 25 to one of the VSA 23 and the VSG 22. The switch fabric 17 may for example comprise directional couplers and/or power splitters/combiners.

The testing front end module 20 further comprise a buffering module 29 which is coupled between the plurality of testing signal interfaces 21a, 21b and the VSG 22 and VSA 23. The buffering module 29 is generally configured to resolve any conflicts in command or request sequence of the different (non-synchronized) backend controllers that are coupled to respective ones of the testing signal interfaces 21a, 21b. Moreover, the buffering module 29 is generally configured to distribute the testing response signals received by the VSA 23 from the different DUTs coupled to the test device interface 25 to corresponding backend controllers over the different testing signal interfaces 21a, 21b, depending on which backend controller is responsible for testing which of the coupled DUTs.

The buffering module 29 comprises a pipelining processor 28 which is configured to receive incoming testing routine signal streams from the various backend controllers over the testing signal interfaces 21a, 21b and to forward them to the VSG 22 according to predefined criteria. For example, the pipelining processor 28 may employ a FCFS strategy (“first-come, first-served”) that prioritizes the testing routine signal streams from the backend controllers according to order in which the streams arrived, without other preferences or bias. Alternatively, the pipelining processor 28 may employ other forwarding strategies that take into account predefined priority criteria for certain ones of the backend controllers, for certain DUTs to be tested or for certain types of testing routines to be performed by the testing front end module.

The pipelining processor 28 is also configured to transmit received testing response signals from the VSA 23 to the backend controllers. To that end, the pipelining processor 28 may distribute the received testing response signals from the VSA 23 according to the testing signal interfaces 21a, 21b to which the corresponding recipient controllers are coupled. The buffering module 29 may comprise a number of controller-specific databases 27a, 27b each of which is associated with a particular controller to temporarily store received testing response signals from the VSA 23 for that controller until the pipelining processor 28 is able to send them on to the associated controller.

Moreover, the controller-specific databases 27a, 27b may also comprise controller-specific configuration data for the VSA 23. While the memory 19 of the VSA 23 may in that case comprise non-specific configuration data and similar firmware that applies to the operation of the VSA 23 in general, the controller-specific configuration data of the controller-specific databases 27a, 27b may be retrieved by the VSA 23 selectively when the functions of the VSA 23 are used for performing a specific testing routine associated with the respective backend controller belonging to the respective one of the controller-specific databases 27a, 27b.

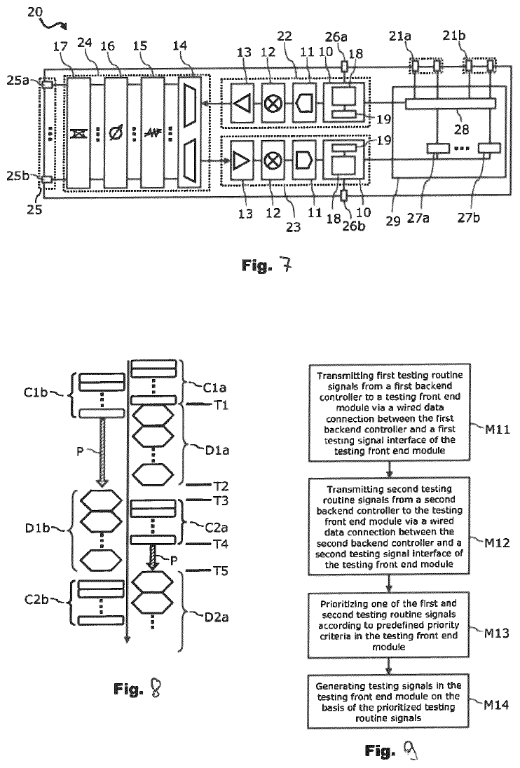

The functionality of the testing front end module 20 in operation will be explained in conjunction with the testing method M1 as depicted in FIG. 9, while resorting to the example of FIG. 8 for a better understanding of the underlying principles.

FIG. 9 schematically illustrates procedural stages of a testing method M1 for testing electronic equipment. The testing method M1 may be performed using the modular testing systems 100a or 200 of one of the FIGS. 5 and 6 and the testing front end module 20 of FIG. 7. The testing method may advantageously be used for testing a plurality of DUTs, such as mobile communication devices or mobile computing devices.

In the testing method, first testing routine signals from a first backend controller are transmitted at M11 to a testing front end module via a wired data connection between the first backend controller and a first testing signal interface of the testing front end module.

At M12, second testing routine signals are transmitted from a second backend controller to the testing front end module via a wired data connection between the second backend controller and a second testing signal interface of the testing front end module.

At M13, one of the first and second testing routine signals is prioritized according to predefined priority criteria in the testing front end module, for example on the basis of FCFS (“first-come, first-served”) criteria. At M14, testing signals are generated in the testing front end module on the basis of the prioritized testing routine signals.

It may optionally be possible to split the generated testing signals and transmit the split testing signals from the testing front end module to one of a plurality of DUTs depending on the prioritized testing routine signals. Furthermore, the non-prioritized testing routine signals may be put on hold, i.e. in a buffered pending state, until the testing signals on the basis of the prioritized testing routine signals have been fully generated, i.e. until the VSG 22 is no longer needed for the first testing routine. Subsequently, the VSG may be freed up for the testing routine signals that have been put on hold, i.e. testing signals may be generated thereafter on the basis of the non-prioritized testing routine signals.

Additionally, in the testing method, testing response signals from the plurality of DUTs may be received which may be stored in one of a plurality of controller-specific databases in the testing front end module. The stored testing response signals may then be transmitted to an associated one of the first and second backend controller via one of the first and second testing signal interface of the testing front end module.

As can be seen from the exemplary signalling sequence chart in FIG. 8, the testing method may be used for buffering testing stages of concurrent testing routines that are accessing the same functional components of a testing front end module, such as the testing front end module 20 of FIG. 7. The time-line of the chart runs from top to bottom, as indicated by the bold arrow in the middle of the chart of FIG. 8. To the right of the arrow, stages of a first testing routine initiated by a first backend controller coupled to a testing front end module are shown, while on the left hand side of the arrow stages of a second, concomitant testing routine initiated independently of the first testing routine by a second backend controller coupled to the testing front end module are indicated.

The first testing routine on the right hand side may for example start with one or more preparatory stages C1a of the first backend controller and/or the respective DUT to be tested. For example, the preparatory stages C1a may involve initiating a testing state of the DUT to be tested, setting a testing configuration within the DUT, ensuring that the DUT is ready for testing, or similar. Those preparatory stages C1a do not resort to the functional capabilities of components of the testing front end module, such as the multiplexer/demultiplexer, the VSG and/or the VSA.

During execution of the preparatory stages C1a of the first backend controller, a second backend controller may initiate preparatory stages C1b of a second testing routine for a different DUT or a different subcomponent of the same DUT as for the first testing routine. The preparatory stages C1a and C1b are not necessarily synchronized with each other, specifically not with regard to their execution timing.

After the preparatory stages C1a of the first testing routine have been finished at time T1, the first backend controller needs to resort to one or more of the functional components of the testing front end module. At time T1, the preparatory stages C1b of the second testing routine are still underway. Thus, when the testing stages D1a of the first testing routine are performed between a time T1 and T2, the second backend controller may not have access to the functional components of the testing front end module since they are still occupied with execution of the testing stages D1a. Thus, the buffering module of the testing front end module will put the testing stages D1b of the second testing routine that would have followed directly on the end of the preparatory stages C1b of the second testing routine on hold, as indicated by the arrow P.

The testing stages of the testing routines may for example include transmitting testing signals to the DUTs, receiving testing response signals from the DUTs, transferring received data from the VSA to the controller individual databases and similar measures.

Only when the testing stages D1a of the first testing routine have been finished at time T2, the pendency of the testing stages D1b of the second testing routine is lifted and the testing stages D1b may commence. During that time, the first testing routine may continue independently from the second testing routine with further preparatory stages C2a that do not need to access the testing front end module and may exemplarily start at time T3. Those further preparatory stages C2a, for example evaluation of testing response signals in the first backend controller, changing the configuration of the DUT for the next test, or similar may be performed in parallel to the testing stages D1b of the second testing routine.

At time T4, when the further testing stages D2a of the first testing routine would have commenced, the first testing routine is put on hold P by the buffering module of the testing front end module. The hold P is only lifted at time T5, when the testing stages D1b of the second testing routine have been finished. The second testing routine may then continue with further preparatory stages C2b, similar to the first testing routine, during the execution of the further testing stages D1b of the second testing routine.

As can be seen from FIG. 8, the idle time of the testing front end module with respect to the first testing routine, i.e. the time between time T2 and T5 may at least partially be put to use for performance of the second testing routine, thereby reducing the overall idle time of the testing front end module and increasing its testing efficiency.

Processing circuits in the specification may, for example, be or comprise a microprocessor or microcontroller. Such processing circuits may be employed in a processing device, for example a central processing unit (CPU) and/or a coprocessor and/or a digital signal processor and/or an embedded processor. The processing circuit may for instance include one, or more, processor cores which can execute the instructions in a memory connected to the processor core. The processor cores may for instance include the logic circuitry required to execute program code in the form of machine code. The processor cores may for instance at least include an instruction decoder, an arithmetic unit, an address generation unit, and a load/store unit. The processing circuit may for example include, in addition to the processor core, inputs/outputs or other components, such as and/or communication interfaces and/or coprocessors and/or analog-to-digital converters and/or clocks and reset generation units, voltage regulators, memory (such as for instance flash, EEPROM, RAM), error correction code logic and/or timers or other suitable components.

In the foregoing specification, the invention has been described with reference to specific examples of embodiments of the invention. It will, however, be evident that various modifications and changes may be made therein without departing from the broader spirit and scope of the invention as set forth in the appended claims. For example, the connections between various elements as shown and described with respect to the drawings may be a type of connection suitable to transfer signals from or to the respective nodes, units or devices, for example via intermediate devices. Accordingly, unless implied or stated otherwise the connections may for example be direct connections or indirect connections.

Because the apparatus implementing the present invention is, for the most part, composed of electronic components and circuits known to those skilled in the art, details of the circuitry and its components will not be explained in any greater extent than that considered necessary as illustrated above, for the understanding and appreciation of the underlying concepts of the present invention and in order not to obfuscate or distract from the teachings of the present invention.

Also, the invention is not limited to physical devices or units implemented in non-programmable hardware, but can also be applied in programmable devices or units able to perform the desired device functions by operating in accordance with suitable program code. Furthermore, the devices may be physically distributed over a number of apparatuses, while functionally operating as a single device. Devices functionally forming separate devices may be integrated in a single physical device. Those skilled in the art will recognize that the boundaries between logic or functional blocks are merely illustrative and that alternative embodiments may merge logic or functional blocks or impose an alternate decomposition of functionality upon various logic or functional blocks.

In the description, any reference signs shall not be construed as limiting the claim. The word “comprising” does not exclude the presence of other elements or steps then those listed in a claim. Furthermore, the terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage. The order of method steps as presented in a claim does not prejudice the order in which the steps may actually be carried, unless specifically recited in the claim.

Skilled artisans will appreciate that the illustrations of chosen elements in the drawings are only used to help to improve the understanding of the functionality and the arrangements of these elements in various embodiments of the present invention. Also, common and well understood elements that are useful or necessary in a commercially feasible embodiment are generally not depicted in the drawings in order to facilitate the understanding of the technical concept of these various embodiments of the present invention. It will further be appreciated that certain procedural stages in the described methods may be described or depicted in a particular order of occurrence while those skilled in the art will understand that such specificity with respect to sequence is not actually required.

What is claimed is:

1. A testing method for testing a plurality of RF devices under test (DUT) by employing a virtual testing instrument having a plurality of RF test channels, the method comprising:
providing, on a first RF test channel of the testing instrument, a first DUT having a first configuration;
providing, on a second RF test channel of the testing instrument, a second DUT having a second configuration;
notifying to the testing instrument the first configuration and second configuration by the first DUT and second DUT, respectively;
determining, by the testing instrument, an expected interference behaviour between the first DUT and second DUT based on the notified first and second configurations;
prioritizing, by the testing instrument, a testing procedure for the first DUT and for the second DUT according to predefined priority criteria; and
generating RF test signals for testing the first and second DUT on the basis of as well the prioritizing of the testing procedure and the determined interference behaviour.

2. The testing method of claim 1, wherein the step of generating RF test signals comprises a synchronizing step such, that a testing procedure for testing the second DUT is started only after the testing procedure for testing the first DUT is finished.

3. The testing method of claim 1, wherein in the step of generating the RF test signals, when testing a first DUT the testing of the second DUT is delayed until a predetermined interference between the first and second RF test channels is below a predefined value.

4. The testing method of claim 3, wherein the predetermined interference is zero.

5. The testing method of claim 1, wherein the step of determining an expected interference behaviour comprises optimizing the test procedure for the first DUT and second DUT such that the interference is reduced.

6. The testing method of claim 1, wherein for determining the expected interference behaviour at least one of the following information are taken into consideration:
the frequency ranges of the RF test signals for testing the first and second DUTs are at least partially overlapping;
an expected reception level of a test receiver within the test instrument conflicts with the level of the RF test signal of a signal generator within the test instrument and the expected signal-noise-ratio (SNR);
RF test signals from two or more signal generators within the test instrument are overlapping in two or more RF test channels.

7. The testing method of claim 1, wherein the first configuration and the second configuration of the first DUT and the second DUT, respectively, comprise at least one of the following test parameters:
a bandwidth used in the respective RF test channel for testing the respective DUT;
a frequency used in the respective RF test channel for testing the respective DUT;
a signal power of a RF test signal used in the respective RF test channel for testing the respective DUT.

8. The testing method of claim 1, wherein the configuration of a DUT is changed from a first testing cycle to a subsequent second testing cycle that is carried out on the same DUT and wherein the corresponding DUT notifies this change of its configuration to the testing instrument.

9. The testing method of claim 1, wherein at least one of the first and second configurations is modified after performing a predefined number of test cycles and wherein the testing of the first and second DUT, respectively, is then repeated or continued on the basis of the modified configuration.

10. The testing method of claim 1, wherein the step of generating the test signals comprises a lock command that contains locking information that are used to lock the testing instrument regardless that the DUT is already transmitting test signals.

11. The testing method of claim 1, wherein the predefined priority criteria comprise FCFS (“first-come, first-served”) criteria.

12. A testing instrument for testing a plurality of RF devices under test (DUT), the testing instrument comprising:
at least two test interfaces for coupling at least two DUTs having different configurations to the testing instrument;
a vector signal generator—VSG—coupled to the test interfaces and configured to generate RF test signals for the testing of at least one of the coupled DUTs;
a vector signal analyser—VSA—coupled to the test interfaces and configured to analyse RF test response signals received from at least one of the coupled DUTs;
a buffering module coupled to the test interfaces and configured:
to receive configuration information from the DUTs coupled to the test interfaces;
to prioritize a testing procedure for a first DUT and for a second DUT according to predefined priority criteria;
to determine an expected interference behaviour between the first DUT and the second DUT based on their notified configurations; and
to generate RF test signals for testing the first DUT and second DUT on the basis of as well the prioritizing of the testing procedure and the determined interference behaviour.

13. The testing instrument of claim 12, wherein the test interface comprises at least four input/output—I/O—ports configured to be connected to a corresponding DUTs.

14. The testing instrument of claim 13, wherein the test interface comprises at least eight I/O ports.

15. The testing instrument of claim 13, further comprising a switch configured to selectively switch the I/O ports of the test interface to one of the VSA and the VSG.

16. The testing instrument of claim 12, wherein the at least two test interfaces comprise at least one of:
a USB port;
a PCIe port;
a Thunderbolt port;
a Firewire port.

17. The testing instrument of claim 12, wherein the buffering module comprises at least two controller-specific databases and wherein the buffering module is further configured to store received RF test response signals from the plurality of DUTs in at least one of the plurality of controller-specific databases.
